(19) United States
(12) Patent Application Publication
(10) Pub. No.: US 2009/0142885 A1
(43) Pub. Date: Jun. 4, 2009

(54) METHOD FOR PROTECTING POROUS LOW-K DIELECTRIC POST CHEMICAL MECHANICAL PLANARIZATION

(76) Inventors: YA OU, Troy, NY (US); Shom Ponoth, Clifton Park, NY (US); Hosadurga Shobha, Niskayuna, NY (US); Terry A. Spooner, Clifton Park, NY (US)

Correspondence Address: FREDERICK W. GIBB, III;Gibb Intellectual Property Law Firm, LLC, 2568-A RIVA ROAD, SUITE 304, ANNAPOLIS, MD, 21401, US

(21) Appl. No.: 11/947,858

(22) Filed: Nov. 30, 2007

(51) Int. Cl. H01L 21/02

(52) U.S. Cl. 438/118; 257/E21.002

(57) ABSTRACT

A method of forming a semiconductor structure chemically-mechanically polishes (CMP) a semiconductor structure before applying a sealant layer over the porous low-k dielectric. The process of applying the sealant layer is a selective process that causes the sealant to adhere to or deposit onto the porous low-k dielectric and to not adhere to the copper conductors. After the sealant layer is formed, the cap is applied. The parylene layer seals the pores in the low-k dielectric which prevents the low-k dielectric layer from being damaged during the cap pre-cleaning process and also prevents the cap material from penetrating into the low-k dielectric.

### BACKGROUND

### Field of the Invention

The embodiments of the invention generally relate to semiconductor structures and semiconductor processing, and more particularly to the utilization of a sealing layer to seal pores in a low-k dielectric after planarization and prior to formation of an overlying cap.

### SUMMARY

For porous low k dielectrics, damage that occurs due to the cap pre-clean operations and the subsequent penetration of the cap material into the dielectric is of concern. This concern is exacerbated for scaled interconnect nodes where the dielectric becomes more and more porous.

Therefore, the embodiments herein use selective materials (such as parylene) as a pore sealant after chemical mechanical planization of the porous dielectric. More specifically, this disclosure presents a method of forming a semiconductor structure that involves chemically-mechanically polishing (CMP) a semiconductor structure that comprises conductors (e.g., copper) in a porous low-k dielectric. After polishing, the method applies a sealant layer over the porous low-k dielectric. The process of applying the sealant layer is a selective process that causes the sealant to adhere to or deposit onto the porous low-k dielectric and to not adhere to the copper conductors. In one optional embodiment, the method can etch back the sealant layer to remove any residual sealant present on the conductors. After the sealant layer is formed, the cap (e.g., N-type cap) is applied. The parylene layer seals the pores in the low-k dielectric which prevents the low-k dielectric layer from being damaged during the cap pre-cleaning process and also prevents the cap material from penetrating into the low-k dielectric.

These and other aspects of the embodiments of the invention will be better appreciated and understood when considered in conjunction with the following description and the accompanying drawings. It should be understood, however, that the following descriptions, while indicating embodiments of the invention and numerous specific details thereof, are given by way of illustration and not of limitation. Many changes and modifications may be made within the scope of the embodiments of the invention without departing from the spirit thereof, and the embodiments of the invention include all such modifications.

### BRIEF DESCRIPTION OF THE DRAWINGS

The embodiments of the invention will be better understood from the following detailed description with reference to the drawings, in which:

FIG. 1 is a flow diagram illustrating a method embodiment of the invention; and

FIG. 2 is a cross-sectional schematic diagram of an embodiment of the invention.

### DETAILED DESCRIPTION OF EMBODIMENTS

The embodiments of the invention and the various features and advantageous details thereof are explained more fully with reference to the non-limiting embodiments that are illustrated in the accompanying drawings and detailed in the following description. It should be noted that the features illustrated in the drawings are not necessarily drawn to scale. Descriptions of well-known components and processing techniques are omitted so as to not unnecessarily obscure the embodiments of the invention. The examples used herein are intended merely to facilitate an understanding of ways in which the embodiments of the invention may be practiced and to further enable those of skill in the art to practice the embodiments of the invention. Accordingly, the examples should not be construed as limiting the scope of the embodiments of the invention.

As mentioned above, damage can occur to low-k dielectrics due to the cap pre-clean operations and the subsequent penetration of the cap material into the dielectric. For example, part of the pre-clean process uses plasma, which can damage the ultra-low or extremely-low porous dielectrics. As mentioned above, this problem is even more of a concern as dielectrics become more and more porous. In order to address these issues, this disclosure provides the use of a selective pore-sealing material after chemical mechanical polishing (CMP). The details regarding low-k dielectrics used within semiconductor structures, pre-clean operations, CMP processing, etc. are discussed in U.S. Patent Publication 2007/0249156 (which is incorporated herein by reference) and the details of such operations are not set forth herein.

One sealant material that can be used with embodiments herein is parylene. Parylene is a general term used to describe a class of poly-p-xylenes that are derived from a dimer wherein X is Hydrogen or a Halogen. Parylene coatings are generally applied from their respective dimers by a deposition process in which the dimer is vaporized, pyrolyzed (that is, cleaved into the monomer vapor form), and supplied to a deposition chamber. Advantageous properties of parylene as a sealant material include selective growth, thermal stability up to 350° C., low dielectric constant as compared to cap materials, etc. The thickness ranges of the parylene can range be any useful range (e.g., from 1-50 nm).

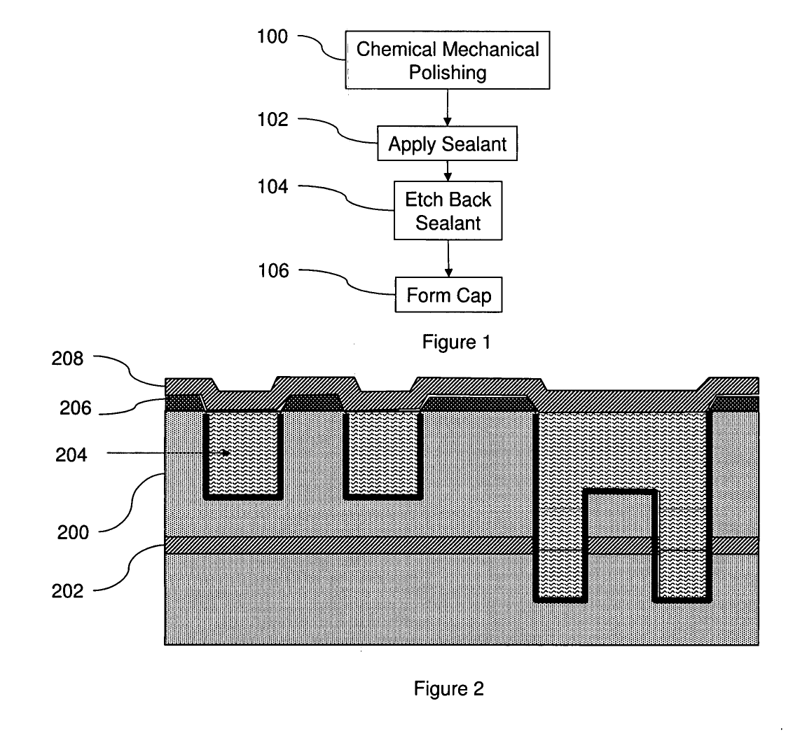

Therefore, as shown in flowchart form in FIG. 1, and in cross-sectional schematic view in FIG. 2, the embodiments herein use selective materials (such as parylene) as a pore sealant 206 after chemical mechanical planization of the porous dielectric 200. More specifically, this disclosure presents a method of forming a semiconductor structure that involves chemically-mechanically polishing (CMP) a semiconductor structure (item 100, FIG. 1). As shown in FIG. 2, the semiconductor structure comprises conductors 204 (e.g., copper) in a porous low-k dielectric 200 and can comprise other layers 202, such different insulators or conductors.

After polishing in item 100, the method applies a sealant 206 layer over the porous low-k dielectric 200 in item 102. The process of applying the sealant 206 layer in item 102 is a selective process that causes the sealant 206 to adhere to the porous low-k dielectric 200 and to not adhere to the copper conductors 204. Parylene adheres to porous dielectrics and not to metals. In one optional embodiment, the method can etch back the sealant 206 layer to remove any residual sealant 206 present on the conductors 204 (Exsitu or Insitu in the N-cap chamber). After the sealant 206 layer is formed, the cap 208 (e.g., SiN, SiC, or N—SiC) is formed/applied in item 106. The parylene layer seals the pores in the low-k dielectric 200 which prevents the low-k dielectric 200 layer from being damages during the cap pre-cleaning process and also prevents the cap 208 material from penetrating into the low-k dielectric 200.

The foregoing description of the specific embodiments will so fully reveal the general nature of the invention that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments of the invention have been described in terms of embodiments, those skilled in the art will recognize that the embodiments of the invention can be practiced with modification within the spirit and scope of the appended claims.

What is claimed is:

1. A method of forming a semiconductor structure comprising:
chemically-mechanically polishing a semiconductor structure comprising conductors in a porous low-k dielectric;
applying a sealant layer over said porous low-k dielectric; and
applying a cap on said sealant layer.

2. The method according to claim 1, all the limitations of which are incorporated herein by reference, wherein said applying of said sealant layer comprises a selective process that causes said sealant to one of adhere and deposit to said porous low-k dielectric and to not adhere and not deposit to said copper conductors.

3. The method according to claim 1, all the limitations of which are incorporated herein by reference, wherein said conductors comprise copper conductors and wherein said cap comprises one of SiN, SiC and N—SiC.

4. A method of forming a semiconductor structure comprising:
chemically-mechanically polishing a semiconductor structure comprising conductors in a porous low-k dielectric;
applying a sealant layer over said porous low-k dielectric;
etching back said sealant layer to remove any residual sealant present on said conductors; and
applying a cap on said sealant layer.

5. The method according to claim 1, all the limitations of which are incorporated herein by reference, wherein said applying of said sealant layer comprises a selective process that causes said sealant to one of adhere and deposit to said porous low-k dielectric and to not adhere and not deposit to said copper conductors.

6. The method according to claim 1, all the limitations of which are incorporated herein by reference, wherein said conductors comprise copper conductors and wherein said cap comprises one of SiN, SiC and N—SiC.
